(19) United States
(12) Patent Application Publication
(10) Pub. No.: US 2008/0246367 A1
(43) Pub. Date: Oct. 9, 2008

(54) TUNED LAMINATED PIEZOELECTRIC ELEMENTS AND METHODS OF TUNING SAME

(75) Inventors: James Paul Fochtman, Williamsburg, VA (US); Paul F. Gregory, Newport News, VA (US)

Correspondence Address: NIXON & VANDERHYE, PC, 901 NORTH GLEBE ROAD, 11TH FLOOR, ARLINGTON, VA, 22203, US

(73) Assignee: AdaptivEnergy, LLC, Hampton, VA (US)

(21) Appl. No.: 11/966,860

(22) Filed: Dec. 28, 2007

Related U.S. Application Data
(60) Provisional application No. 60/882,624, filed on Dec. 29, 2006.

(51) Int. Cl. H01L 41/04; H01L 41/22

(52) U.S. Cl. 310/312; 29/25.35; 310/367

(57) ABSTRACT

A piezoelectric element comprises a piezoelectric ceramic wafer bonded to a substrate, with a surface profile of the substrate being non-uniformly configured to affect the spring rate of the piezoelectric element. For example, in one example embodiment the substrate has its profile configured so that its stiffness is modified or non-uniform along at least one axis of the substrate. The nature of the non-uniform surface profile can acquire various configurations or patterns.

This application claims the priority and benefit of U.S. Provisional Patent application 60/882,624, filed Dec. 29, 2006, entitled “TUNED LAMINATED PIEZOELECTRIC ELEMENTS AND METHODS OF TUNING SAME”, which is incorporated herein by reference in its entirety.

### BACKGROUND

I. Technical Field

The present invention pertains to laminated piezoelectric elements, and particularly but not exclusively to laminated piezoelectric elements of the type that are employed in actuators.

II. Related Art and Other Considerations

As is well known, a piezoelectric material is polarized and will produce an electric field when the material changes dimensions as a result of an imposed mechanical force. This phenomenon is known as the piezoelectric effect. Conversely, an applied electric field can cause a piezoelectric material to change dimensions.

A laminated piezoelectric actuator is manufactured by bonding (e.g., by using adhesive or other means) one or more piezoelectric ceramic wafer(s) or element(s) to a substrate(s). One purpose of bonding the piezoelectric ceramic to the substrate is to maintain compressive load on the ceramic element such that when it is energized, it does not fracture under tension. A common substrate material is metal, often stainless steel, however; this technique can be used for virtually all substrates.

One type of laminated piezoelectric element is known as a ruggedized laminated piezoelectric or RLP®, which has a piezoelectric wafer which is laminated to a stainless steel substrate and preferably also has an aluminum cover laminated thereover. Examples of such RLP® elements, and in some instances pumps employing the same, are illustrated and described in one or more of the following: PCT Patent Application PCT/US01/28947, filed 14 Sep. 2001; U.S. patent application Ser. No. 10/380,547, filed Mar. 17, 2003, entitled “Piezoelectric Actuator and Pump Using Same”; U.S. patent application Ser. No. 10/380,589, filed Mar. 17, 2003, entitled “Piezoelectric Actuator and Pump Using Same”, and U.S. patent application Ser. No. 11/279,647 filed Apr. 13, 2006, entitled “PIEZOELECTRIC DIAPHRAGM ASSEMBLY WITH CONDUCTORS ON FLEXIBLE FILM”, all of which are incorporated herein by reference.

The bonding or lamination of a piezoelectric element such as a piezoelectric ceramic wafer to a substrate or other metallic layer can be performed using a hot melt adhesive. Bonding or lamination using a hot melt adhesive (including a polyimide adhesive such as that known as LaRC-SI™) is taught by one or more of the following United States patent documents (all of which are incorporated herein by reference): US Patent Publication US 2004/0117960 A1 to Kelley; U.S. Pat. No. 6,512,323 to Forck et al.; U.S. Pat. No. 5,849,125 to Clark; U.S. Pat. No. 6,030,480 to Face; U.S. Pat. No. 6,156,145 to Clark; U.S. Pat. No. 6,257,293 to Face; U.S. Pat. No. 5,632,841 to Hellbaum; U.S. Pat. No. 6,734,603 to Hellbaum. Other adhesive formulations or bonding/lamination techniques are taught by one or more of the following (all of which are incorporated herein by reference): U.S. Provisional Patent Application 60/877,630, entitled “HOT MELT THERMOSETTING POLYIMIDE ADHESIVES CONTAINING DIACETYLENE GROUPS”; U.S. Provisional Patent Application 60/882,677, entitled “POLYIMIDE/COPOLYIMIDE FILMS WITH LOW GLASS TRANSITION TEMPERATURE FOR USE AS HOT MELT ADHESIVES”; and PCT Patent Application PCT/US07/89006, filed Dec. 28, 2007, entitled “POLYIMIDE/COPOLYIMIDE FILMS WITH LOW GLASS TRANSITION TEMPERATURE FOR USE AS HOT MELT ADHESIVES”.

Once a piezoelectric actuator element has been manufactured, it can be used in many ways. Most applications use lamination-based piezoelectric actuators by applying voltage across the piezoelectric ceramic element, causing the piezoelectric ceramic element to expand or contract. This change in shape of the piezoceramic element causes the substrate to bend. In most applications this bending is used to perform work. Among the most fundamental performance characteristics of a piezoelectric actuator are free displacement, spring rate and blocking force rate.

The free displacement is defined as displacement measured at a certain location on a piezoelectric actuator while changing from one voltage extreme to the other. Blocking force is the measured force and displacement while mechanically forcing the actuator from an energized displacement to the “at rest” displacement. The slope of the blocking force verses the displacement line generated during the above test is known as the blocking force rate. Lastly, the spring rate is measured as the slope of the spring force verses the displacement. Data for the spring rate is collected by mechanically forcing the actuator from the “at rest” displacement, while the piezoelectric element is not energized, to the maximum displacement found during the free displacement. At a minimum, these three performance characteristics are needed to design the laminated piezoelectric device into applications utilizing the bending motion to perform work.

Unfortunately, a laminated piezoelectric element manufactured with a substrate does not always provide the optimum spring rate for all applications.

### BRIEF SUMMARY

Different applications using piezoelectric actuators to perform useful work require unique balance of many mechanical performance characteristics. Among these performance characteristics is the actuators spring rate. To optimize the actuators performance in an application, it is desirable to “tune” the actuator to the optimum performance characteristic to each application. Disclosed herein are method and structure for allow tuning of a piezoelectric actuator's spring rate, thereby allowing for optimal performance in the application.

In one of its aspects, the technology concerns a piezoelectric element which comprises a piezoelectric ceramic wafer which is preferably bonded to a substrate. A surface profile of the substrate is non-uniformly configured to affect the spring rate of the piezoelectric element. For example, in one example embodiment the substrate has its profile configured so that its stiffness is modified or non-uniform along at least one axis of the substrate.

The nature of the non-uniform surface profile can acquire various configurations or patterns. In one example embodiment, the surface profile of the substrate comprises grooves formed in a pattern on the substrate In differing implementations, the pattern of grooves can be one or more of a ribbed pattern, a star pattern, or a radial pattern formed on the substrate. The ribbed pattern, star pattern, and radial pattern are particularly but not exclusively appropriate when the substrate has an essentially quadrilateral (e.g., rectangular) shape. In other implementations, the pattern can have a circular or arcuate shape, e.g., arcuate or circular grooves formed in a concentric pattern on the substrate.

In differing embodiments the non-uniform surface profile can result from removing material to a partial thickness of the substrate to form, e.g., patterns such as those summarized above. Alternatively, in differing embodiments the non-uniform surface profile can result from removing material through an entire thickness of the substrate, e.g., providing plural holes or slots (of same or differing sizes) through the entire thickness of the substrate.

In another of its aspects, the technology concerns a method of fabricating a piezoelectric element. The method basically comprises providing a piezoelectric ceramic wafer bonded to a substrate and (either before or after the bonding) adjusting a spring rate of the piezoelectric element by modifying a surface profile of the substrate. For example, the act of modifying the surface profile of the substrate can comprise removing material from the substrate to effect moment of inertia of the substrate. As another example, the act of modifying the surface profile of the substrate can comprise etching a pattern on the substrate. As yet another example, the act of modifying the surface profile of the substrate can comprise modifying stiffness of the substrate along a first axis of the substrate. The act of modifying the surface profile of the substrate can comprise removing material to a partial thickness of the substrate. Alternatively, the act of modifying the surface profile of the substrate comprises removing material through an entire thickness of the substrate, e.g., providing plural holes or slots (of same or differing sizes) through the entire thickness of the substrate.

### BRIEF DESCRIPTION OF THE DRAWINGS

The foregoing and other objects, features, and advantages of the invention will be apparent from the following more particular description of preferred embodiments as illustrated in the accompanying drawings in which reference characters refer to the same parts throughout the various views. The drawings are not necessarily to scale, emphasis instead being placed upon illustrating the principles of the invention.

FIG. 1A is a top or plan view of a piezoelectric element according to a first example embodiment.

FIG. 1B is a sectioned side view of the piezoelectric element according to the example embodiment of FIG. 1A.

FIG. 2A is a top or plan view of a piezoelectric element according to a second example embodiment.

FIG. 2B is a sectioned side view of the piezoelectric element according to the example embodiment of FIG. 2A.

FIG. 3A is a top or plan view of a piezoelectric element according to a third example embodiment.

FIG. 3B is a sectioned side view of the piezoelectric element according to the example embodiment of FIG. 3A.

FIG. 4A is a top or plan view of a piezoelectric element according to a fourth example embodiment.

FIG. 4B is a sectioned side view of the piezoelectric element according to the example embodiment of FIG. 4A.

FIG. 5 is a top or plan view of a piezoelectric element according to a fifth example embodiment.

FIG. 6 is a top or plan view of a piezoelectric element according to a sixth example embodiment.

FIG. 7 is a top or plan view of a piezoelectric element according to a seventh example embodiment.

FIG. 8 is a top or plan view of a piezoelectric element according to an eighth example embodiment.

### DETAILED DESCRIPTION

In the following description, for purposes of explanation and not limitation, specific details are set forth such as particular architectures, interfaces, techniques, etc. in order to provide a thorough understanding of the present invention. However, it will be apparent to those skilled in the art that the present invention may be practiced in other embodiments that depart from these specific details. That is, those skilled in the art will be able to devise various arrangements which, although not explicitly described or shown herein, embody the principles of the invention and are included within its spirit and scope. In some instances, detailed descriptions of well-known devices, circuits, and methods are omitted so as not to obscure the description of the present invention with unnecessary detail. All statements herein reciting principles, aspects, and embodiments of the invention, as well as specific examples thereof, are intended to encompass both structural and functional equivalents thereof. Additionally, it is intended that such equivalents include both currently known equivalents as well as equivalents developed in the future, i.e., any elements developed that perform the same function, regardless of structure.

In one of its aspects, the technology concerns a piezoelectric element. The piezoelectric element comprises a piezoelectric ceramic wafer bonded to a substrate. A surface profile of the substrate is configured to affect the spring rate of the piezoelectric element. For example, in one example embodiment the substrate has its profile configured so that its stiffness is modified or non-uniform along at least one axis of the substrate.

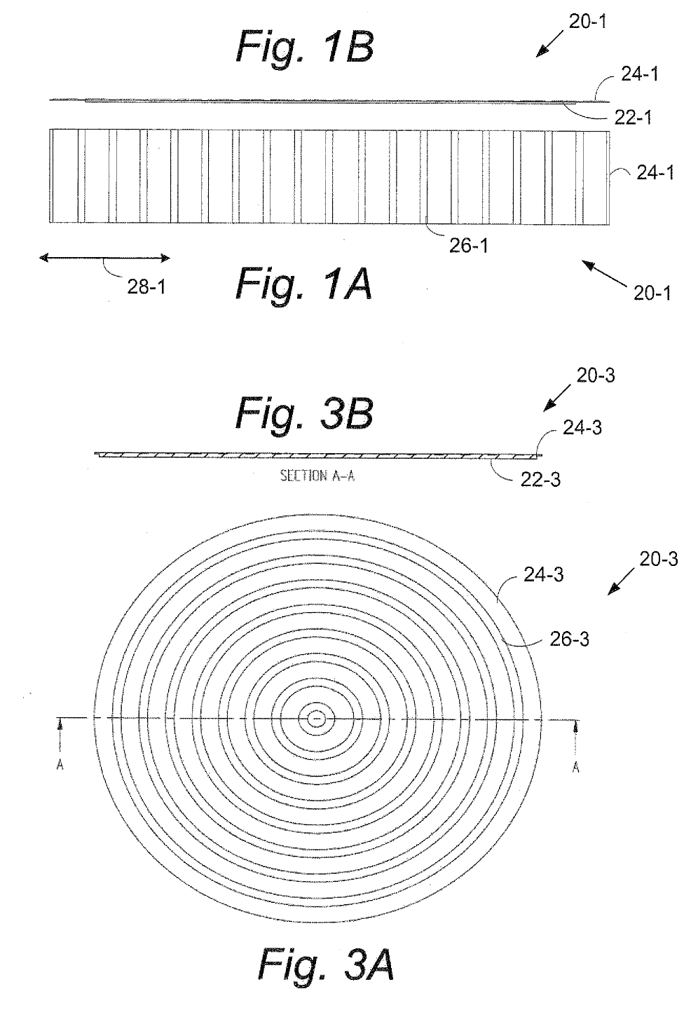

The nature of the non-uniform surface profile can acquire various configurations or patterns. FIG. 1A and FIG. 1B show a first example embodiment of a piezoelectric device 20-1 comprising piezoelectric wafer 22-1 bonded to substrate 24-1. In the example embodiment of FIG. 1A and FIG. 1B, both the piezoelectric wafer 22-1 and the substrate 24-1 have a rectangular shape. The surface profile of the substrate comprises grooves 26-1 formed in a ribbed pattern on the substrate 24-1. In the ribbed pattern (best seen in FIG. 1B), grooves 26-1 are formed parallel to one another and perpendicular to a major axis 28-1 of substrate 24-1.

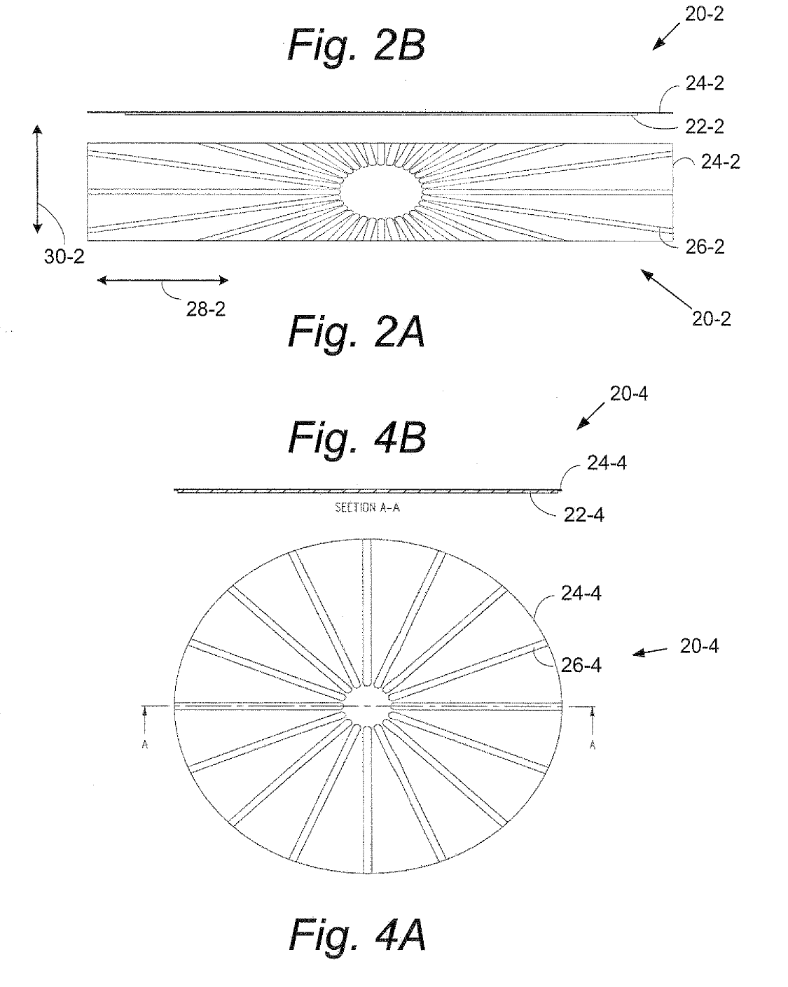

FIG. 2A and FIG. 2B show a second example embodiment of a piezoelectric device 20-2 comprising piezoelectric wafer 22-2 bonded to substrate 24-2. Both the piezoelectric wafer 22-2 and the substrate 24-2 have a rectangular shape. The surface profile of the substrate comprises grooves 26-2 formed in a star pattern on the substrate 24-2.

FIG. 3A and FIG. 3B show a third example embodiment of a piezoelectric device 20-3 comprising piezoelectric wafer 22-3 bonded to substrate 24-3. Both the piezoelectric wafer 22-3 and the substrate 24-3 have a circular shape. The surface profile of the substrate comprises arcuate or circular grooves 26-3 formed in a concentric pattern on the substrate 24-3.

FIG. 4A and FIG. 4B show a fourth example embodiment of a piezoelectric device 20-4 comprising piezoelectric wafer 22-4 bonded to substrate 24-4. Both the piezoelectric wafer 22-4 and the substrate 24-4 have a circular shape. The surface profile of the substrate comprises grooves 26-4 formed in radial or a star pattern on the substrate 24-4.

The foregoing embodiments are illustrative examples of piezoelectric devices in which the non-uniform surface profile can result from removing material to a partial thickness of the substrate to form, e.g., patterns such as those summarized above. Alternatively, and in differing embodiments such as those described below by way of non-limiting example, the non-uniform surface profile can result from removing material through an entire thickness of the substrate, e.g., providing plural holes or slots (of same or differing sizes) through the entire thickness of the substrate.

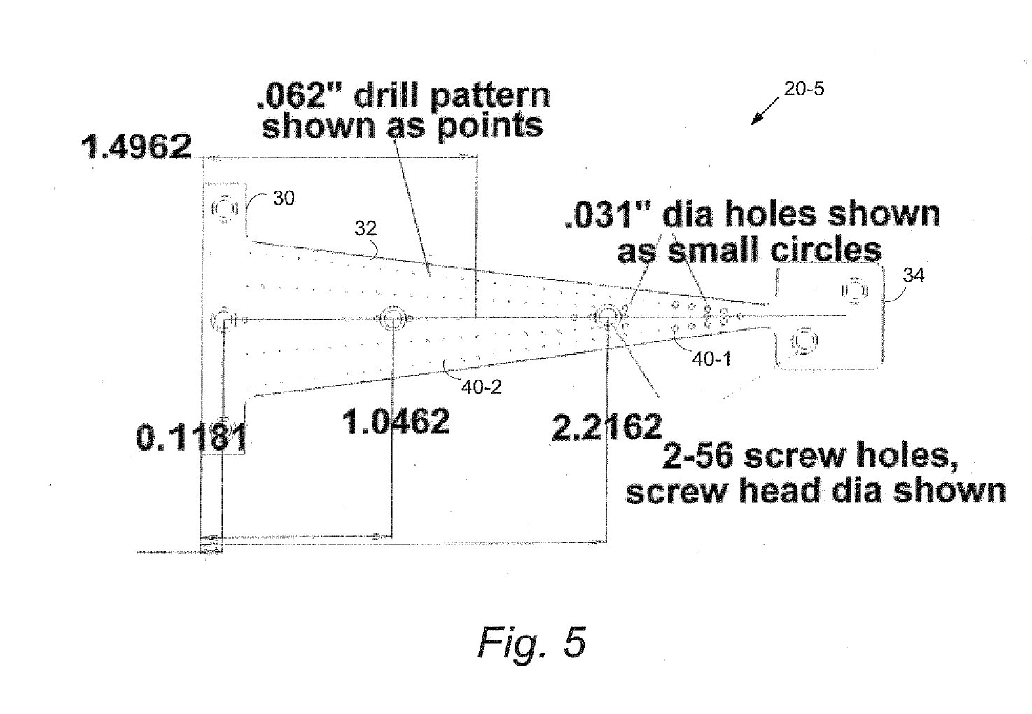

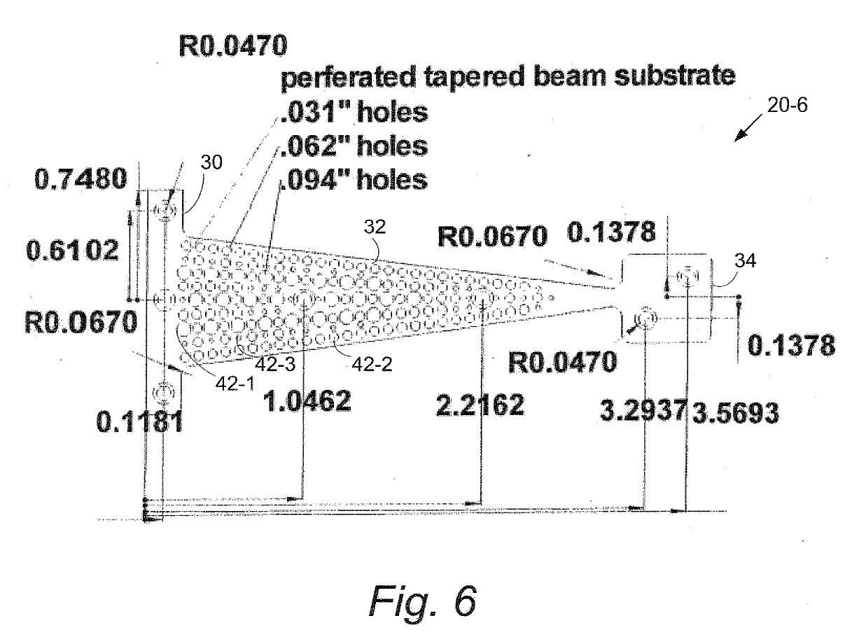

In the above regard, FIG. 5-FIG. 8 provide illustrations of example embodiments of piezoelectric devices 20-5 through 20-8, respectively, which are configured for cantilever positioning within a host device. Each of piezoelectric devices 20-5 through 20-8 are essentially flat, spring-like piezoelectric members which comprise an essentially rectangular attachment shoulder portion 30, an elongated triangular mid portion 32, and a quadrilateral (e.g., square) distal portion 34. The example piezoelectric devices 20-5 through 20-8 also optionally further comprise one or more (e.g., two) screw holes 36 which can facilitate optional attachment or fastening of a mass or the like which can piggyback (e.g., selectively or interchangeably) on the piezoelectric device and thereby serve to adjust natural (resonant) vibration frequency. Means other than screw holes can be utilized to secure or adhere a passenger mass or the like to the piezoelectric device for adjusting natural (resonant) vibration frequency. Measurements of the respective portions of a non-limiting, example implementation of the piezoelectric devices 20-5 through 20-8 are shown, e.g., in FIG. 6.

The piezoelectric devices 20-5 through 20-7 are examples wherein the non-uniform surface profile can result from plural holes (of same or differing sizes) being provided through the entire thickness of the substrate. The piezoelectric device 20-5 of FIG. 5 comprises two discrete zones of holes provided in triangular mid portion 32. By “discrete” zone is meant that like-sized holes primarily occupy the zone. A first zone near the triangular apex of mid portion 32 comprises holes 40-1 of a first diameter and a second zone near the base of mid portion 32 comprises holes 40-2 of a second diameter. In the example, non-limiting, illustrated implementation of FIG. 5, the first diameter is 0.031 inch while the second diameter is 0.062 inch.

The piezoelectric device 20-6 of FIG. 6 comprises holes of plural differing sizes interspersed in triangular mid portion 32. For example, the triangular mid portion 32 of the piezoelectric device 20-6 of FIG. 6 has holes 42-1 of a first diameter; holes 42-2 of a second diameter; and holes 42-3 of a third diameter. In the example, illustrated implementation of FIG. 6, the first diameter is 0.094 inch; the second diameter is 0.031 inch; and the third diameter is 0.062 inch. The interspersal of the holes of differing sizes can be according to a pattern. In particular, an example pattern shown in FIG. 6 is of row that are arranged essentially parallel to isosceles edges of triangular mid portion 32. Some rows typically comprise the same sized type hole, although other rows may have holes of differing sizes arranged (e.g., alternated) along the row. Adjacent rows generally comprise holes of differing sizes. Some rows terminate prior to reaching the apex of triangular mid portion 32.

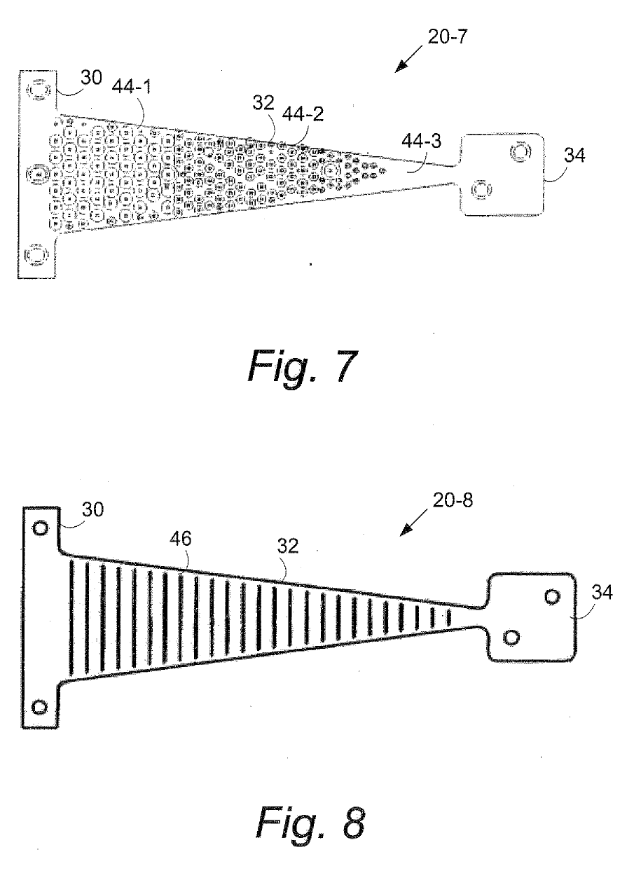

The triangular mid portion 32 of the piezoelectric device 20-7 of FIG. 7 comprises three zones: proximal zone 44-1 which is populated with holes of a first diameter; mid-zone 44-2 which is populated with holes of a second diameter (the second diameter being smaller than the first diameter); and distal zone 44-1 which is essentially devoid of holes.

The piezoelectric device 20-8 is a representative example wherein the non-uniform surface profile can result from plural slots (of same or differing sizes) through the entire thickness of the substrate being provided through the entire thickness of the substrate. In the example embodiment of FIG. 8, essentially parallel, linear slots 46 are provided. The slot 46 are arranged parallel to the base of triangular mid portion 32, e.g., parallel to a major axis of shoulder portion 30. So arranged, the slots 46 having decreasing length ranging from proximate shoulder portion 30 to proximate distal portion 34. It will be appreciated that slots of other than linear shape can be provided in lieu of or addition to the linear slots.

It will further be understood that arrangements of grooves, holes, or slots are not limited to the examples described above, but in other embodiments can assume other configurations.

Moreover, the shape of the substrates are not limited to those illustrated and/or described herein. While in some example embodiments the substrates may be essentially quadrilateral, in other example embodiments the substrates may be circular, oval, elliptical, triangular, of other geometrical shapes, or even irregular or a combination of geometrical or irregular shapes. Further, the particular patterns of features which express material removal are not limited to the shapes of the substrates which serve in the respective embodiments to host the patterns, since the same or similar patterns can be provided in substrates having shapes other than those on/for which the patterns are illustrated.

The removal of material as described in any embodiment above can be effected from either side of the substrate comprising the piezoelectric devices, and such removal can occur prior to or subsequent to lamination of the substrate with the piezoelectric wafer. Moreover, for those embodiments having holes or slots, such holes or slots can be formed by drilling or cutting. During any mode of the method in which the lamination is subsequent to the substrate modification, a film or adhesive employed during the lamination operation can fill the voids of the holes or slots while still affecting the overall spring rate of the device. Although the film has a smaller role in the stiffness of the device than the metallic substrate, film which flows into substrate voids (e.g., holes or slots) during lamination can play a significant factor in the stiffness of the device and therefore need to be considered in the overall design.

In another of its aspects, the technology concerns a method of fabricating a piezoelectric element. The method basically comprises providing a piezoelectric ceramic wafer bonded to a substrate and (either before or after the bonding) adjusting a spring rate of the piezoelectric element by modifying a surface profile of the substrate. For example, the act of modifying the surface profile of the substrate can comprise removing material from the substrate to effect moment of inertia of the substrate. As another example, the act of modifying the surface profile of the substrate can comprise etching a pattern on the substrate. As yet another example, the act of modifying the surface profile of the substrate can comprise modifying stiffness of the substrate along a first axis of the substrate. The act of modifying the surface profile of the substrate can comprise removing material to a partial thickness of the substrate. Alternatively, the act of modifying the surface profile of the substrate comprises removing material through an entire thickness of the substrate, e.g., providing plural holes or slots (of same or differing sizes) through the entire thickness of the substrate. Specific aspects of the method can be implemented in order to achieve grooves, holes, slots, or other surface configurations according to patterns or features such as those encompassed by the embodiments embraced by this technology.

Thus, in accordance with the present technology, the spring rate of a laminated piezoelectric actuator element can be optimized for each application by modifying the moment of inertia of the device by selectively removing material from the substrate, thus modifying the performance of the actuator. This modification to the substrate can configure the stiffness of the device such that the stiffness is different along different axes of the actuator. For example, in the rectangular shaped piezoelectric actuator of FIG. 1A and FIG. 1B, stiffness is needed along the minor axis but not along the major axis 28-1. The piezoelectric device 20-2 of FIG. 2A and FIG. 2B shows a pattern which improves a balance of stiffness between the minor axis 30-2 and major axis 28-2 for a rectangular element.

Although the illustrated examples show only round and rectangular piezoelectric actuators, the principles of the structure and method herein described apply also to any shape of piezoelectric ceramic bonded to any shape substrate. The illustrated patterns are thus only examples and are not in any way considered to be the only appropriate patterns usable with this method or structure of optimizing the stiffness of piezoelectric actuators.

The present technology is useful, e.g., in laminated piezoelectric actuator devices in which it is desired to develop or have a spring rate other than that provided by the geometry of the laminated device with a standard (unmodified) substrate. This technology can be used to tune the spring rate of any shape piezoelectric actuator to achieve the optimum performance for a specific application.

The present technology is not limited to piezoelectric devices of the ruggedized laminated type mentioned above, but is also applicable to bi-morph devices. An example employment of one or more embodiments encompassed by the present technology is described in U.S. Provisional Patent Application 61/017,483 filed on Dec. 28, 2007, entitled “Magnetic Impulse Energy Harvesting Device and Method”, which is incorporated herein by reference in its entirety. One particular benefit for a ruggedized laminated piezoelectric in an application such as energy harvesting is that the spring rate is softened through selective removal of material in the substrate while increasing the substrate thickness when compared to a similar device for which the substrate has not been modified. The increased thickness of the substrate with reduced spring rate of tuned embodiments such as those described herein provides a higher voltage output due to increased strain induced into the piezoelectric material (e.g., the piezoelectric wafer) while using similar end weights at ends of the piezoelectric device.

Although the description above contains many specificities, these should not be construed as limiting the scope of the invention but as merely providing illustrations of some of the presently preferred embodiments of this invention. Thus the scope of this invention should be determined by the appended claims and their legal equivalents. Therefore, it will be appreciated that the scope of the present invention fully encompasses other embodiments which may become obvious to those skilled in the art, and that the scope of the present invention is accordingly to be limited by nothing other than the appended claims, in which reference to an element in the singular is not intended to mean “one and only one” unless explicitly so stated, but rather “one or more.” All structural, chemical, and functional equivalents to the elements of the above-described preferred embodiment that are known to those of ordinary skill in the art are expressly incorporated herein by reference and are intended to be encompassed by the present claims. Moreover, it is not necessary for a device, process, or method to address each and every problem sought to be solved by the present invention, for it to be encompassed by the present claims. Furthermore, no element, component, or method step in the present disclosure is intended to be dedicated to the public regardless of whether the element, component, or method step is explicitly recited in the claims. No claim element herein is to be construed under the provisions of 35 U.S.C. 112, sixth paragraph, unless the element is expressly recited using the phrase “means for.

What is claimed is:

1. A method of fabricating a piezoelectric element comprising:
providing a piezoelectric ceramic wafer bonded to a substrate;
adjusting a spring rate of the piezoelectric element by modifying a surface profile of the substrate so that the surface profile is non-uniform.

2. The method of claim 1, wherein the act of modifying the surface profile of the substrate comprises removing material from the substrate to effect moment of inertia of the substrate.

3. The method of claim 1, wherein the act of modifying the surface profile of the substrate comprises etching a pattern on the substrate.

4. The method of claim 1, wherein the act of modifying the surface profile of the substrate comprises modifying stiffness of the substrate along a first axis of the substrate.

5. The method of claim 4, wherein the act of modifying the surface profile of the substrate comprises modifying stiffness of the substrate also along a second axis of the substrate.

6. The method of claim 1, wherein the act of modifying the surface profile of the substrate comprises removing material to a partial thickness of the substrate.

7. The method of claim 1, wherein the act of modifying the surface profile of the substrate comprises providing grooves in a pattern on the substrate.

8. The method of claim 1, wherein the act of modifying the surface profile of the substrate comprises providing grooves in one of a ribbed pattern, a star pattern, and a radial pattern on the substrate.

9. The method of claim 1, wherein the act of modifying the surface profile of the substrate comprises providing arcuate or circular grooves in a concentric pattern on the substrate.

10. The method of claim 1, wherein the act of modifying the surface profile of the substrate comprises removing material through an entire thickness of the substrate.

11. The method of claim 10, wherein the act of modifying the surface profile of the substrate comprises providing plural holes or slots through the entire thickness of the substrate.

12. The method of claim 11, wherein the act of modifying the surface profile of the substrate comprises providing plural holes or slots of differing sizes through the entire thickness of the substrate.

13. The method of claim 1, further comprising modifying the surface profile of the substrate to achieve optimum performance for a specific application.

14. A piezoelectric element comprising:
a piezoelectric ceramic wafer bonded to a substrate;
a surface profile of the substrate being non-uniformly configured to affect the spring rate of the piezoelectric element.

15. The piezoelectric element of claim 14, wherein the substrate has its stiffness modified along at least one axis of the substrate.

16. The piezoelectric element of claim 14, wherein the surface profile of the substrate comprises grooves in a pattern on the substrate.

17. The piezoelectric element of claim 14, wherein the pattern is one of a ribbed pattern, a star pattern, and a radial pattern on the substrate.

18. The piezoelectric element of claim 14, wherein the substrate comprises grooves in a radial pattern on the substrate.

19. The piezoelectric element of claim 14, wherein the surface profile of the substrate comprises arcuate or circular grooves in a concentric pattern on the substrate.

20. The piezoelectric element of claim 14, wherein the substrate comprises a feature having material removed to a partial thickness of the substrate.

21. The piezoelectric element of claim 14, wherein the substrate comprises a feature having material removed through an entire thickness of the substrate.

22. The piezoelectric element of claim 14, feature comprises plural holes or slots formed through in the substrate.

23. The piezoelectric element of claim 14, wherein the feature comprise plural holes or slots of differing sizes formed in the substrate.
